(19) United States
(12) Patent Application Publication
(10) Pub. No.: US 2006/0284640 A1
(43) Pub. Date: Dec. 21, 2006

(54) Structure of circuit board and method for fabricating the same

(76) Inventors: Shing-Ru Wang, Hsin-chu (TW); Hsien-Shou Wang, Hsin-chu (TW); Shih-Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/449,214

(22) Filed: Jun. 7, 2006

(30) Foreign Application Priority Data
Jun. 20, 2005 (TW) 094120386

(51) Int. Cl. G01R 31/26

(52) U.S. Cl. 324/765

(57) ABSTRACT

A structure of a circuit board and a method for fabricating the same are proposed. A first and a second dielectric layers are formed on a first and a second carrier boards respectively, and a first and a second circuit layers are formed on the first and second dielectric layer respectively. Then, between the first circuit layer of the first carrier board and the second circuit layer of the second carrier board is laminated a third dielectric layer, and thus the first circuit layer is embedded between the first and the third dielectric layers, and the second circuit layer is embedded between the second and the third dielectric layers. The two carrier boards are removed to form a core board with the first and the second circuit layers. Afterwards, a third and a fourth circuit layers are formed on the first and the second dielectric layers respectively. After a plurality of conductive vias are formed between those dielectric layers, the first, second, third and fourth circuit layers can be electrically connected through the conductive vias, thereby forming the circuit board with high density circuit layout.

### CROSS-REFERENCE TO RELATED APPLICATION

This application claims benefit under 35 USC 119 to Taiwan Application No. 094120386, filed Jun. 20, 2005.

### FIELD OF THE INVENTION

The present invention relates to structure of circuit boards, and methods for fabricating the same, and more particularly, to a circuit board provided with multi-layer circuit, and a method for fabricating the circuit board.

### BACKGROUND OF THE INVENTION

As the electronic industry continues to boom, the trend in the development of electronic products is heading in the direction of small size but with high integration, high functionality and high performance, and the integration of electronic components will continue to rise. In order to satisfy the requirements of high integration and miniaturization for semiconductor packages, a circuit board provided with active/passive components and circuits is developed from a double-layer structure into a multi-layer circuit board. This is achieved by employing the interlayer connection technique to enlarge the usable area of circuit board with limited space, so that integrated circuits of high wiring density can be incorporated, thereby fitting a larger quantity of circuits and components onto the same units of area.

Additionally, in response to the calculation requirements of high-end chips such as microprocessors, chipsets, and graphic chips; circuit board with interconnecting circuits needs to enhance functions such as chip signal transfer, bandwidth improvement, and control of resist to facilitate the development of packages with high I/O values. However, in order to meet the developmental trend of small size, multi-functions, high-speed, and high-frequency, the development of circuit board has to focus on achieving fine pitch circuit and micro via. The circuit size in current production process of circuit board has been reduced from the traditional size of 100 microns to 30 microns, and relevant research continues to concentrate on attaining smaller circuit sizes.

To increase the circuit density of circuit board, the industry has developed a technique called “build-up”; this technique stacks multiple dielectric layers and circuit layers in an inter-layer fashion on the surface of a core circuit board, and opens conductive via in the dielectric layers to electrically connect the circuits of top and bottom layers. The build-up process of circuits is a critical factor in deciding the circuit density on circuit board.

FIGS. 1A to 1G show the methods for fabricating circuit board with additional layers using prior art. As shown in FIG. 1A, the first step is to prepare a double-layer core board 100 by covering copper foil on both sides of a dielectric layer, and drill a plurality of through holes 102 in the core board. As shown in FIG. 1B, inner circuit layer 103 is formed by plating the surface of core board 100 with copper and patterning it, and the inner wall of through hole 102 is also plated with a metal layer. Subsequently, as shown in FIG. 1C, a conductive or non-conductive filling material 11 (for example, an insulating ink or copper-containing conductive paste) is filled into the remaining space within through hole 102, thereby forming a PTH (plated through hole) 102a that electrically connects the inner circuit layer 103 on the top and bottom surfaces of core board 100. Then as shown in FIG. 1D, the method of scrubbing is applied to remove excessive filling material 11, so that the surface regularity of circuits in core board is ensured; at this point a core circuit board 10 is completed. After that, as shown in FIG. 1E, a dielectric layer 12 is formed on inner circuit layers 103 of the top and bottom surface on core circuit board 10. By using laser drilling technique to form a plurality of openings 120 on dielectric layer 12, the inner circuit layer 103 of core circuit board 10 is connected. In the following step shown in FIG. 1F, a conductive layer 13 is formed by electrolessly plating copper on the surface of dielectric layer 12 and opening 120; before electroplating is carried out, a patterned resist layer 14 is added on the conductive layer 13, and finally a circuit layer 15 is formed on the surface of conductive layer 13. Next, as illustrated in FIG. 1C; the resist layer 14 is removed to allow etching to take place, so that the conductive layer 13 previously covered by resist layer 14 can be removed as well. In this way, the processes mentioned above can be repeated to form more dielectric layers and build-up circuit layers, thereby resulting in circuit board with multi-layer circuits.

The main disadvantage is that processes like through hole plugging and scrubbing in the production of core circuit board increase the cost of making circuit boards. More importantly, the formation of many plated through holes on the surface of core circuit board not only hampers miniaturized packaging, but also lowers the circuit density on the surface of core circuit board. This is because the presence of Plated through holes requires additional space for pad extending from the Plated through holes themselves during the making of patterned circuit layer on the build-up circuit layers of top and bottom surfaces of core circuit board, so that conductive via can be formed. As a result, a larger surface area on circuit board is needed for distributing circuits, and circuit density has to be reduced due to the need to circumvent Plated through holes. In addition to this, the diameter of common plated through hole is approximately 100 μm or more, but the diameter of conductive via is approximately 50 μm in comparison, which can also be formed by the method of electroplating the circuits. Obviously, the making of plated through hole does not favor the formation of fine pitch circuit structure.

Moreover, in respect to a circuit board with multi-layer circuits produced according to the aforementioned processes, when a signal is to be delivered from the topmost layer to the bottommost layer, the signal has to start from the topmost build-up circuit layer, travel through the top build-up circuit layer and each and every conductive via between the top circuit layers to reach the core circuit board, then through the inner plated through hole within the core circuit board, past each and every conductive via between the bottom build-up circuit layers and the bottom build-up circuit layer to finally reach the bottommost layer of the circuit board. The excessive length of signal transfer pathway readily results in the enhancement of electricity and thus leads to problems like cross-talk or noise, which weakens the electrical quality of the product.

Furthermore, with regard to a circuit board with multi-layer circuits made according to the aforementioned processes, it is necessary to prepare a core circuit board prior to the addition of dielectric layer and circuit layer on the same core circuit board itself, so that the overall production can be successfully completed. As a result, this requirement further complicates the production processes, and increases the time and costs needed for production accordingly.

Therefore, a circuit board structure and method for fabricating the same are urgently needed for resolving the problems of low circuit density resulted from prior arts, of overlong signal transfer pathway, of increased circuit board thickness, of complicated production processes, and of increased production time and costs.

### SUMMARY OF THE INVENTION

In light of the disadvantages of previous techniques described above, a primary objective of the present invention is to provide a circuit board structure and a method for fabricating the same, by which circuit density on the circuit board can be increased.

Another objective of the invention is to provide a circuit board structure and a method for fabricating the same, which can shorten signal transfer pathway and thus improves the quality of circuit board.

Another objective of the invention is to provide a circuit board structure and a method for fabricating the same, by which the production processes can be simplified, and production time and costs can be cut.

A further objective of the invention is to provide a circuit board structure and a method for fabricating the same, by which the thickness of circuit board is reduced so as to meet the developmental trend of miniaturization.

In order to accomplish the objectives described above, the present invention provides a method for fabricating a circuit board structure that includes: firstly, forming a first and a second dielectric layers on a first and a second carrier boards respectively, then forming a first and a second circuit layers on the first and the second dielectric layers respectively; this is followed by laminating a third dielectric layer between the first circuit layer of the first carrier board and the second circuit layer of the second carrier board, so that the first circuit layer is embedded between the first and the third dielectric layers, and the second circuit layer is embedded between the second the third dielectric layers. Subsequently, the two carrier boards are removed to form a core board embedded with the first and the second circuit layers, then a third circuit layer is formed on the first dielectric layer, and a fourth circuit layer is formed on the second dielectric layer. Finally, a plurality of conductive vias are formed between the dielectric layers described above; so that the first, second, third and fourth circuit layers can be electrically connected by the conductive vias.

In accordance with the processes described in previous paragraph, the circuit board structure resulted from the present invention includes: a core board, and it is made of a first, a second, and a third dielectric layers, and a first and a second circuit layers, the first circuit layer is embedded between the first and the third dielectric layers, and the second circuit layer is embedded between the second and the third dielectric layers; the third circuit layer is formed on the outer surface of the first dielectric layer of the core board, a plurality of conductive vias are formed between the first and the third dielectric layers, so that the third circuit layer can be electrically connected to the first and the second circuit layers by physically going through the first dielectric layer, and by a plurality of conductive vias going through the first and the third dielectric layers. And the fourth circuit layer is formed on the outer surface of the second dielectric layer of the core board, a plurality of conductive vias are formed between the second and the third dielectric layers, so that the fourth circuit layer can be electrically connected to the second and the first circuit layers by physically going through the second dielectric layer, and by a plurality of conductive vias going through the second and the third dielectric layers.

Therefore, according to the present invention, the circuit board structure and the method for fabricating the same are to prepare a core board embedded with a first and a second circuit layers in advance, then form a third and a fourth circuit layers on the top and the bottom surfaces of this core board, and electrically connect the first, second, third, and fourth circuit layers by a plurality of conductive vias formed within the core board, so that a circuit board with multi-layer circuits can be quickly formed, thereby cutting the time and costs of production, and thus bypassing problems like complicated production processes and increased production time and costs, which are resulted from prior art with the requirement of drilling, electroplating, through hole plugging, and multiple stacking processes.

The circuit board made according to the present invention does not need the plated through holes for electrically connecting the circuits between the layers; it only requires the presence of conductive vias formed within the core board for electrically connecting circuits between circuit board layers. As a result, the circuit density on the surface of circuit board is increased, thus bypassing the problem of low circuit density, which is resulted from the need to circumvent the plated through holes.

In addition, the circuit board structure and the method for fabricating the same according to the present invention are to laminate two different pieces of carrier board together; the first carrier board having a first dielectric layer and a first circuit layer, and the second carrier board having a second dielectric layer and a second circuit layer, so that the first circuit layer is embedded between the first and the third dielectric layers, and the second circuit layer is embedded between the second and the third dielectric layers. Subsequently, the first and the second carrier boards are removed to form a core board embedded with the first and the second circuit layers, then a third and a fourth circuit layers are formed on the outer surface of the first and the second dielectric layers of the core board; a plurality of conductive vias are then formed between the dielectric layers described above, thereby electrically connecting the first, second, third, and fourth circuit layers. As a result, the signal transfer pathway is shortened, which results in the reduction of electrical induction; and consequently facilitates its application in high-frequency electronic devices.

Furthermore, according to the present invention, the first and the second circuit layers are embedded within the core board, and the third and the fourth circuit layers are formed directly on the outer surface of the first and the second dielectric layers of the core board. As a result, there is no need for a core circuit board, and this consequently leads to the reduction of the thickness of circuit board, thereby meeting the developmental demand of miniaturization.

### BRIEF DESCRIPTION OF THE DRAWINGS

The present invention can be more fully comprehended by reading the following detailed description of the preferred embodiments, with reference made to the accompanying drawings, wherein:

FIGS. 1A to 1G (PRIOR ART) are schematic flow charts showing the stepwise processes for fabricating the structure of a circuit board;

FIGS. 2A to 2H are schematic cross-sectional views showing the stepwise processes for fabricating the structure of a circuit board according to the present invention; and

FIG. 3 is a schematic cross-sectional view of the structure of a circuit board according to another preferred embodiment of the present invention.

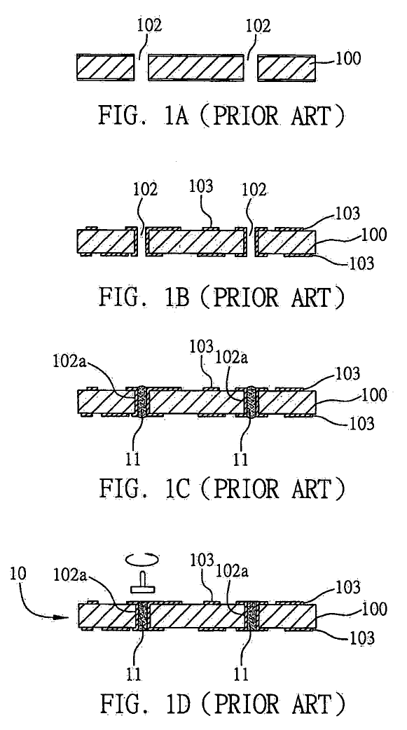

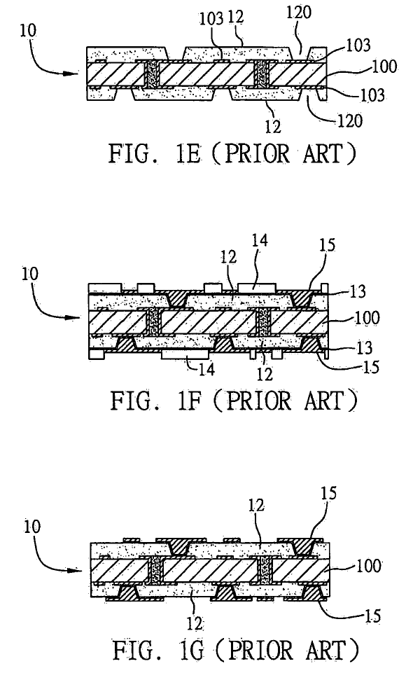

### DETAILED DESCRIPTION OF THE PREFERRED EMBODIMENT

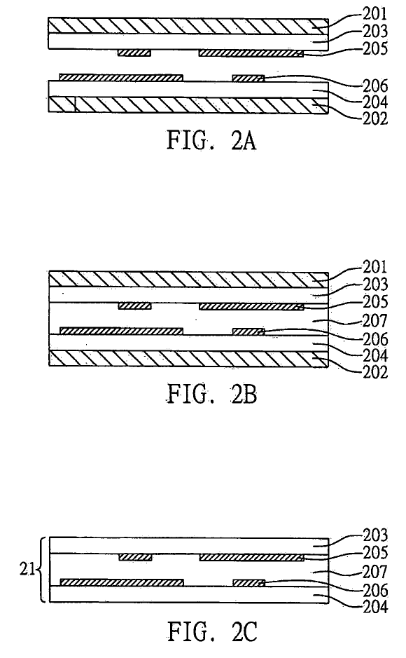

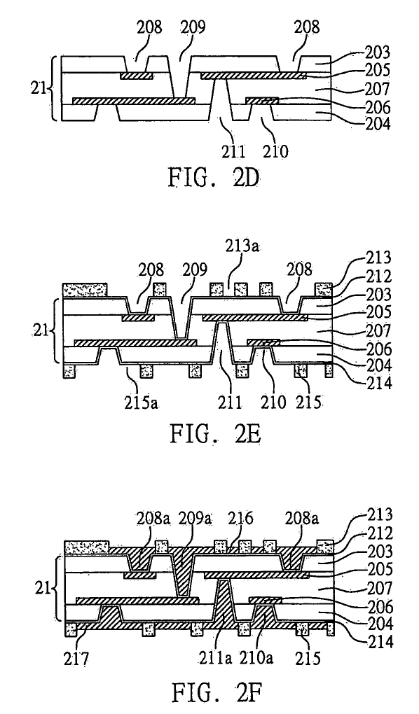

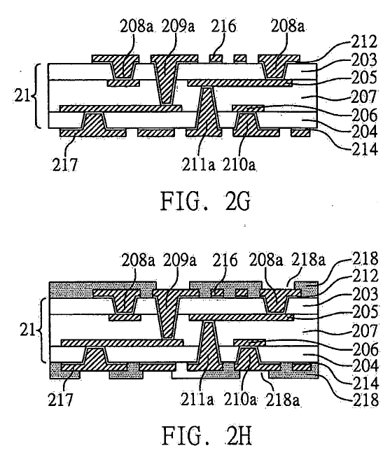

FIGS. 2A to 2H are schematic cross-sectional views showing the stepwise processes of a method for fabricating a circuit board structure according to the present invention.

Referring to FIG. 2A, a first carrier board 201 and a second carrier board 202 are prepared at first, then a first dielectric layer 203 is formed on the first carrier board 201, and a first circuit layer 205 is formed on the first dielectric layer 203. Then a second dielectric layer 204 is formed on the second carrier board 202, and a second circuit layer 206 is formed on the second dielectric layer 204. The first dielectric layer 203 and the second dielectric layer 204 described above can be made of materials like epoxy resin, polyimide, cyanate ester, glass fiber, bismaleimide triazine, or mixed substances consisted of fiber glass and epoxy resin. The first dielectric layer 203 and the second dielectric layer 204 are made of the same materials, but can also be changed to different materials according to the actual requirement of design. The carrier board can be a metal board or a non-metal board of adequate strength. On the other hand, the production method of the first and the second circuit layers is a known prior art, it is not the focus of the main technical content in this case, hence this method will not be described here.

Referring to FIG. 2B, a third dielectric layer 207 is prepared, then the third dielectric layer 207 is laminated between the first circuit layer 205 of the first carrier board 201 and the second circuit layer 206 of the second carrier board 202, so that the first circuit layer 205 is embedded between the first dielectric layer 203 and the third dielectric layer 207, and the second circuit layer 206 is embedded between the second dielectric layer 204 and the third dielectric layer 207.

Referring to FIG. 2C, the first carrier board 201 and the second carrier board 202 are removed, thereby forming a core board 21 embedded with the first circuit layer 205 and the second circuit layer 206.

Referring to FIG. 2D, laser drilling or mechanical drilling is used to form a plurality of first vias 208 in the first dielectric layer 203, thereby exposing parts of the first circuit layer 205, then a plurality of second vias 209 are formed in the first dielectric layer 203 and the third dielectric layer 207 to expose parts of the second circuit layer 206; a plurality of third vias 210 are formed in the second dielectric layer 204 to expose parts of the second circuit layer 206, and a plurality of fourth vias 211 are formed in the second dielectric layer 204 and the third dielectric layer 207 to expose parts of the first circuit layer 205. The parts of circuit layers exposed by the vias 208, 209, 210, and 211 described above are to be used as the pad for dividing the electrical connectivity between each circuit layer.

Referring to FIG. 2E, a first conductive layer 212 is formed on the outer surface of the first dielectric layer 203, on the surface of the first via 208, and on the surface of the second via 209. On the other hand, a second conductive layer 214 is formed on the outer surface of the second dielectric layer 204, on the surface of the third via 210, and on the surface of the fourth via 211. The first conductive layer 212 and the second conductive layer 214 described above are the required electricity conducting pathway for metal materials used in the electroplating process afterwards, they can be made of metal, metal alloy, layers of metal deposition, or high-molecular materials filled with conductive substances. In addition, the first conductive layer 212 and the second conductive layer 214 can be formed by methods like chemical deposition (for example, electroless plating), physical vapor deposition (for example, sputtering), or chemical vapor deposition.

Still referring to FIG. 2E, a first resist layer 213 is formed on the first conductive layer 212, then parts of the first conductive layer 212 are exposed by removing parts of resist layer 213; a second resist layer 215 is formed on the second conductive layer 214, then parts of the second conductive layer 214 are exposed by removing parts of resist layer 215. The first resist layer 213 and the second resist layer 215 described above can be a dry film or liquid photoresist like a photoresist layer; they are formed on the surface of the first conductive layer 212 and the second conductive layer 214 either by the method of printing, spincoating, or adhering, and they are patterned by the method of exposing and developing, so that the first and the second resist layers 213 and 215 respectively, cover only parts of the first conductive layer 212 and the second conductive layer 214, thereby forming a plurality of plated openings that are 213a and 215a, and the position of openings 213a and 215a should at least correspond to the position of 208, 209, 210, and 211, which are the first, second, third, and fourth vias.

Referring to FIG. 2F, electroplating is carried out to form a third circuit layer 216 on the opening 213a in the first resist layer, then a first conductive via 208a and a second 209a are formed in correspondence to the first and the second vias, so that the third circuit layer 216 can be electrically connected to the first circuit layer 205 and the second circuit layer 206 by the first and the second conductive vias, 208a and 209a respectively; electroplating is also carried out to form a fourth circuit layer 217 on the opening 215a in the second resist layer, then a third and a fourth conductive vias 210a and 211a are formed in correspondence to the third and the fourth vias, so that the fourth circuit layer 217 can be electrically connected to the second circuit layer 206 and the first circuit layer 205 by the third and the fourth conductive vias, 210a and 211a respectively. The present invention employs conductive via for electrically connecting the circuit layers, which in turn increases circuit density. Therefore, according to the present invention, the third and the fourth circuit layers on circuit board surface is electrically connected to the first and the second circuit layers by the conductive vias formed in the core board. As a result, the signal transfer pathway is shortened, and the electrical induction of the transfer pathway is reduced, thereby lowering cross-talk and noise, and also facilitating its use in high-frequency electronic devices, improving the quality of signal transfer in circuit board, and eliminating the need for a core circuit board, which decreases the thickness of circuit board and meets the developmental trend of miniaturization.

Referring to FIG. 2C; the first resist layer 213 and the part of first conductive layer 212 covered by 213 are removed, and the second resist layer 215 and the part of second conductive layer 214 covered by 215 are also removed. There are many methods available for the removal of the first resist layer 213, the second resist layer 215, and the parts of first conductive layer 212 and second conductive layer 214 covered by 213 and 215; because these methods are well known in the industry, they will not be further elaborated here.

Referring to FIG. 2H, a solder mask layer 218 is formed on the third circuit layer 216 and the fourth circuit layer 217, and a plurality of openings 218a are also formed in the solder mask layer 218 to expose the third and the fourth circuit layers, 216 and 217 respectively; the exposed parts are to serve as the electrically connecting pad.

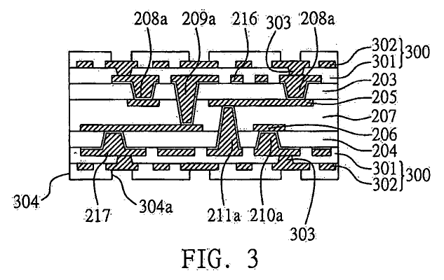

Referring to FIG. 3, in case build-up layer is required, a build-up circuit layer 300 can be formed on top of the third circuit layer 216 and the fourth circuit layer 217 according to the circuit layer build-up processes in the circuit board production method of the present invention. The circuit layer build-up processes include the following steps: forming dielectric layers on the third and the fourth circuit layers at first, forming vias on the dielectric layers and using electroplating process to form circuit layers and conductive vias on the dielectric layers and vias. Therefore, the build-up circuit layer 300 is comprised of a dielectric layer 301 and a circuit layer 302 stacked upon dielectric layer 301, and the circuit layer 302 is electrically connected to the third circuit layer 216 and the fourth circuit layer 217 by the conductive via 303 in dielectric layer 301. Afterwards, a solder mask layer 304 can be formed on the outer surface of the build-up circuit layer, and a plurality of openings 304a are also formed in the solder mask layer 304 to expose parts of the build-up circuit layer that are to be used as pads for electrical connectivity.

By the methods described above, the circuit board structure made according to the present invention mainly includes: a core board 21; this core board is comprised of a first dielectric layer 203, a second dielectric layer 204, a third dielectric layer 207, a first circuit layer 205, and a second circuit layer 206; it should be noted that the first circuit layer 205 is embedded between the first and the third dielectric layers, 203 and 207 respectively, and the second circuit layer 206 is embedded between the second and the third dielectric layers, 204 and 207 respectively; the third circuit layer 216 is formed on the outer surface of the first dielectric layer 203 of core board 21, and the third circuit layer 216 is electrically connected to the first circuit layer 205 and the second circuit layer 206 by the first conductive via 208a going through first dielectric layer 203, and by the second conductive via 209a going through the first and the third dielectric layers, 203 and 207 respectively; the fourth circuit layer 217 is formed on the outer surface of the second dielectric layer 204 of core board 21, and the fourth circuit layer 217 is electrically connected to the second circuit layer 206 and the first circuit layer 205 by the third conductive via 210a going through the second dielectric layer 204, and by the fourth conductive via 211a going through the second and the third dielectric layers, 204 and 207 respectively. Moreover, forming the solder mask layers 218 on the circuit board structure include the third and the fourth circuit layers, 216 and 217 respectively.

In addition, the circuit board structure made according to the present invention can include at least one build-up circuit layer 300 formed on top of the third and the fourth circuit layers.

Therefore, the circuit board structure and method for fabricating the same in accordance to the present invention include these steps: first of all, preparing a core board embedded with a first and a second circuit layers, then forming a third and a fourth circuit layers on the top and bottom surfaces of the core board, and electrically connecting the first, second, third, and fourth circuit layers by the conductive vias formed in the core board.

The circuit board structure and method for fabricating the same, according to the present invention, mainly consist of the following steps: a first carrier board having a first dielectric layer and a first circuit layer is laminated together with a second carrier board having a second dielectric layer and a second circuit layer, so that the first circuit layer is embedded between the first and the third dielectric layers, and the second circuit layer is embedded between the third and the second dielectric layers, this is followed by the removal of the first and the second carrier boards to form a core board embedded with the first and the second circuit layers, then a third and a fourth circuit layers are directly formed on the outer surface of the first and the second dielectric layers of the core board. Afterwards, a plurality of conductive vias are formed between the dielectric layers mentioned above, thereby electrically connecting the first, second, third, and fourth circuit layers. Doing so not only allows a multi-layer circuit board to be swiftly formed, thereby reducing production time and costs, but also bypasses the needs of drilling, electroplating, via plugging, and multiple stacking processes in the prior arts; these needs can give rise to problems like production complication and increased production time and costs. On the other hand, the signal transfer pathway can also be shortened, which will further reduce the electrical induction of the signal transfer pathway, thereby facilitating its application in high-frequency electronic devices.

Additionally, the circuit board structure made according to the present invention does not require Plated through holes for electrically connecting circuits between the layers of a circuit board, it only requires the presence of conductive vias formed in the core board for this purpose, thus increasing the circuit density on the surface of a circuit board; this bypasses the need to circumvent Plated through holes and so the circuit density on circuit board surface will not be reduced like it used to be.

Moreover, according to the present invention, the first and the second circuit layers are embedded within the core board, and the third and the fourth circuit layers are directly formed on the outer surface of the first and the second dielectric layers of the core board, hence a core circuit board device is no longer required, which leads to the reduction of the thickness of circuit board and thereby meeting the demand of miniaturization.

Furthermore, according to the present invention, further build-up processes can be carried out to add additional circuit layers on the outer surface of the circuit layer of the circuit board, so that a circuit board having multi-layer circuits and the required electrical property can be formed.

The invention has been described using exemplary preferred embodiments. However, it is to be understood that the scope of the invention is not limited to the disclosed embodiments. In other words, it is intended to cover various modifications and similar arrangements. Therefore, the scope of the claims should be interpreted in the broadest sense so as to encompass all such modifications and similar arrangements.

What is claimed is:

1. A method for fabricating a circuit board structure, comprising the steps of:
forming a first and a second dielectric layers on a first and a second carrier boards, and forming a first and a second circuit layers on the first and the second dielectric layers;
laminating a third dielectric layer between the first circuit layer of the first carrier board and the second circuit layer of the second carrier board, so that the first circuit layer is embedded between the first and the third dielectric layers, and the second circuit layer is embedded between the second and the third dielectric layers, then removing the first and the second carrier boards to form a core board embedded with the first and the second circuit layers; and
forming a third circuit layer on an outer surface of the first dielectric layer, a fourth circuit layer on an outer surface of the second dielectric layer, and a plurality of conductive vias through the first and second dielectric layers so as to electrically connect the first, second, third, and fourth circuit layers.

2. The method of claim 1, wherein the stepwise processes for fabricating the third circuit layer are comprised of:
forming a first via in the first dielectric layer to expose a part of the first circuit layer, and forming a second via in the first and the third dielectric layers to expose a part of the second circuit layer;
forming a conductive layer on the outer surface of the first dielectric layer and the surfaces of the first and the second vias;
forming a resist layer on this conductive layer, and also forming openings in the resist layer to expose a the part of conductive layer covered by the resist layer; and
carrying out electroplating so that a third circuit layer is formed in the openings of this resist layer, then a first and a second conductive vias are also formed in the first and the second vias, so that the third circuit layer is electrically connected to the first and the second circuit layers by the first and the second conductive vias.

3. The method of claim 2, further comprising the removal of the resist layer and the part of conductive layer covered by this resist layer.

4. The method of claim 2, wherein the conductive layer is made of either metal or conductive polymer.

5. The method of claim 2, wherein the resist layer is formed on the surface of the conductive layer by one of printing, spincoating, and adhering methods, and patterned by exposing and developing.

6. The method of claim 1, further comprising a solder mask layer being formed on the third and the fourth circuit layers, and a plurality of openings are also formed in the solder mask layer to expose the part of third and fourth circuit layers to be used as the electrically connecting pad.

7. The method of claim 1, further comprising the processes for building up additional circuit layers, so that build-up circuit layers can be formed on top of the third and the fourth circuit layers.

8. The method of claim 7, further comprising a solder mask layer being formed on the outer surface of the build-up circuit layers, and a plurality of openings are also formed in the solder mask layer to expose the parts of the build-up circuit layers to be used as the electrically connecting pad.

9. The method of claim 7, wherein the structure of the build-up circuit layer is consisted of a dielectric layer and the circuit layer stacked upon this dielectric layer, and the circuit layer is electrically connected to the third and the fourth circuit layers by the conductive vias formed in the dielectric layer.

10. The method of claim 1, wherein the stepwise processes for fabricating the fourth circuit layer are comprised of:
forming a third via in the second dielectric layer to expose parts of the second circuit layers, and forming a fourth via in the second and the third dielectric layers to expose parts of the first circuit layer;
forming a conductive layer on the outer surface of the second dielectric layer and the surfaces of the third and the fourth vias;
forming a resist layer on the conductive layer, and also forming openings in the resist layer to expose parts of the conductive layer; and
carrying out electroplating to form a fourth circuit layer in the openings of the resist layer, then a third and a fourth conductive vias are also formed in the third and the fourth vias, so that the fourth circuit layer is electrically connected to the second and the first circuit layers by the third and the fourth conductive vias.

11. The method of claim 10, further comprising the removal of the resist layer and the conductive layer covered by this resist layer.

12. The method of claim 10, wherein the resist layer is made of either metal or conductive polymer.

13. The method of claim 10, wherein the resist layer is formed on the surface of the conductive layer by either printing, spincoating, or adhering, and then the resist layer is patterned by exposing and developing.

14. A circuit board structure, comprising:
a core board having a first, a second, and a third dielectric layers, and a first and a second circuit layers; the first circuit layer is embedded between the first and the third dielectric layers, and the second circuit layer is embedded between the second and the third dielectric layers;
a third circuit layer formed on the outer surface of the first dielectric layer of the core board, and the third circuit layer is electrically connected to the first and the second circuit layers by a plurality of conductive vias going through the first dielectric layer, and by a plurality of conductive vias going through the first and the third dielectric layers; and
a fourth circuit layer formed on the outer surface of the second dielectric layer of the core board, and the fourth circuit layer is electrically connected to the second and the first circuit layers by a plurality of conductive vias going through the second dielectric layer, and by a plurality of conductive vias going through the second and the third dielectric layers.

15. The circuit board of claim 14, wherein a solder mask layer is formed on top of the third and the fourth circuit layers, and openings are also formed in the solder mask layer to expose the parts of third and fourth circuit layers to be used as the electrically connecting pad.

16. The circuit board of claim 14, further comprising at least one build-up circuit layer formed on top of the third and the fourth circuit layers.

17. The circuit board of claim 16, further comprising a solder mask layer formed on the outer surface of the build-up circuit layer, and a plurality of openings formed in the solder mask layer to expose the parts of build-up circuit layer to be used as the electrically connecting pad.

18. The circuit board of claim 16, the structure of the build-up circuit layer is consisted of a dielectric layer and a circuit layer stacked upon this dielectric layer, the circuit layer is electrically connected to the third and the fourth circuit layers by a plurality of conductive vias formed in the dielectric layer.
